(19) United States
(12) Patent Application Publication
(10) Pub. No.: US 2014/0070367 A1
(43) Pub. Date: Mar. 13, 2014

(54) SEMICONDUCTOR DEVICE

(71) Applicant: KABUSHIKI KAISHA TOSHIBA, Tokyo (JP)

(72) Inventors: Minoru KAWASE, Kanagawa (JP); Hideaki SAI, Hyogo (JP); Shigehiro HOSOI, Hyogo (JP)

(21) Appl. No.: 13/919,366

(22) Filed: Jun. 17, 2013

(30) Foreign Application Priority Data
Sep. 10, 2012 (JP) 2012-198391

(51) Int. Cl. H01L 23/552; H01L 29/66

(52) U.S. Cl. CPC H01L 23/552; H01L 29/66106
USPC 257/532; 438/381

(57) ABSTRACT

According to one embodiment, the semiconductor device according to the embodiment of the present disclosure is provided with a first semiconductor layer, a second semiconductor layer, a ninth semiconductor layer formed on the second semiconductor layer, a third semiconductor layer, a first region enclosed with the third semiconductor layer, a fourth semiconductor layer, a second region on the second semiconductor layer, a fifth semiconductor layer, a sixth semiconductor layer, a first terminal connected to the first semiconductor layer, and a second terminal connected to the fifth semiconductor layer and the sixth semiconductor layer.

### CROSS-REFERENCE TO RELATED APPLICATION

This application is based upon and claims the benefit of priority from Japanese Patent Application No. 2012-198391, filed on Sep. 10, 2012; the entire contents of which are incorporated herein by reference.

### FIELD

Embodiments described herein relate to a semiconductor device as an embodiment.

### BACKGROUND

Information is exchanged via an interface between information processing units. The interface is electrically connected to integrated circuits in the information processing units via input and output terminals. If an ESD (Electro Static Discharge) occurs across the input and output terminals, the integrated circuits connected thereto may be damaged. To protect the integrated circuit from the ESD, an ESD protecting device is connected between the input and output terminals and a ground terminal in the information processing unit. To protect the integrated circuit from an overvoltage or ESD condition, the breakdown voltage of the ESD protecting device is set to a value slightly higher than the normal voltage of the input and output signals of the device. For example, when the voltage of the input and output signals is 5 V, the breakdown voltage of the ESD protecting device is set to be about 7 V.

The capacitance of the ESD protecting device increases with a decrease of the breakdown voltage of the ESD protecting device. If the capacitance of the ESD protecting device increases, the impedance is lowered, and the input and output signals will leaked across or through the ESD protecting devices reducing the performance of the device that the ESD is intended to protect. As the frequency of signals propagating through the interface becomes high, the impedance is further lowered. For this reason, it is required that the capacitance of the ESD protecting device be lowered to reduce the leakage of normal device voltage signals across the ESD protection device.

However, the ESD protecting device includes diodes. For this reason, it is necessary to reduce p-n junction areas of the diodes to lower the capacitance thereof. However, the on-state resistance is raised if the p-n junction area is reduced. If the on-state resistance of the ESD protecting device is raised, then when an ESD occurs, the resulting current from the discharge which flows through the ESD protecting device is reduced, while the current flowing to a integrated circuit side increases. As a result, the ESD resistance of the information processing unit having the ESD protecting device is decreased. Therefore, an ESD protecting device with smaller capacitance and lower on-state resistance is desired.

### DESCRIPTION OF THE DRAWINGS

FIG. 1 shows an equivalent circuit of an ESD protecting device according to a first embodiment.

FIG. 2 is a schematic cross section showing the main parts of the ESD protecting device according to the first embodiment.

FIG. 3 is a schematic plan view showing the main parts of the ESD protecting device according to the first embodiment.

FIG. 4 is a schematic cross section showing the main parts of an ESD protecting device according to a second embodiment.

FIG. 5 is a schematic cross section showing the main parts of an ESD protecting device according to a third embodiment.

FIG. 6 is a schematic plan view showing the main parts of the ESD protecting device according to the third embodiment.

FIG. 7 shows an equivalent circuit of the ESD protecting device according to the third embodiment.

FIG. 8 shows an equivalent circuit of the ESD protecting device according to a fourth embodiment.

### DETAILED DESCRIPTION

Embodiments provide a semiconductor device with both a small capacitance and a low on-state resistance as compared to prior devices.

In general, according to one embodiment, the present disclosure will be explained with reference to the figures. The shape, dimension, size relation, etc., of each element in the figures are not necessarily limited to those shown in the figure in an actual reduction to practice, but can be appropriately changed in the range where the effects of the present disclosure can be obtained. In the following explanation, a first conductive type is p-type, and a second conductive type is n-type. However, these conductive types can also be reversed, i.e., the opposite conductivity types. As a semiconductor, silicon is used as an example; however, compound semiconductors such as silicon carbide (SiC) and gallium nitride (GaN) can also be used. As an insulator, silicon oxide is used an example; however other insulators such as silicon nitride (SiN), silicon oxynitride (SiNO), and alumina (Al₂O₃) can also be used. In this case the n-type conductive type is indicated by n⁺, n, and n⁻, the n-type dopant concentration is lower in this n⁺, n, to n⁻sequence. For the p-type, similarly, the p-type dopant concentration is highest to lowest in order of p⁺, p, and p⁻.

### First Embodiment

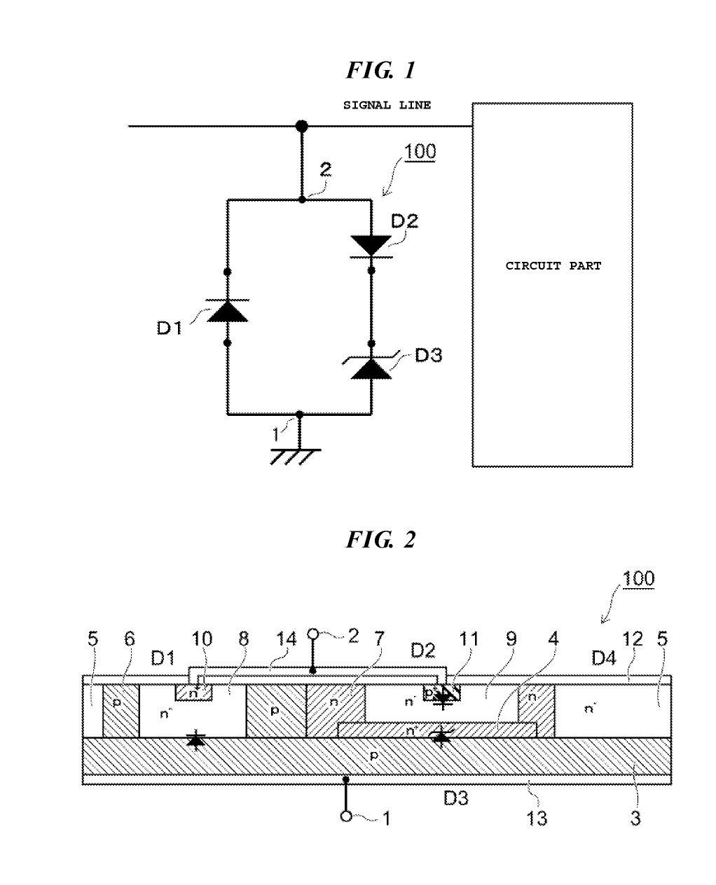

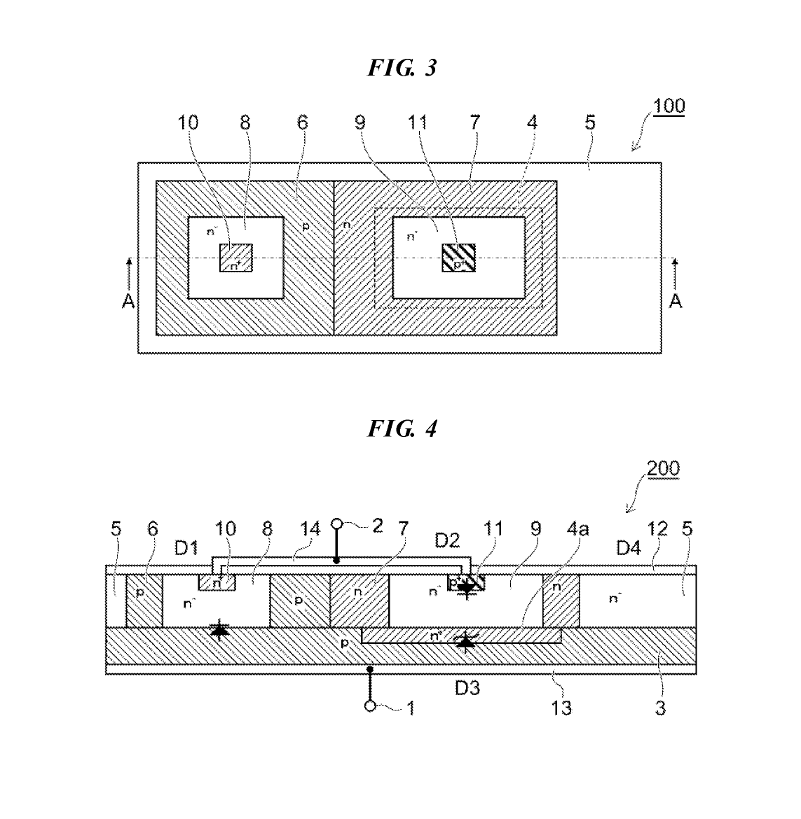

With reference to FIG. 1 through FIG. 3, the semiconductor device (hereinafter, referred to as the ESD protecting device) according to the first embodiment of the present disclosure will be explained. FIG. 1 shows an equivalent circuit and a usage example of the ESD protecting device according to the first embodiment. FIG. 2 is a schematic cross section showing the main parts of the ESD protecting device according to the first embodiment. FIG. 3 is a schematic plan view showing the main parts of the ESD protecting device according to the first embodiment. In the plan view of FIG. 3, an interlayer dielectric 12 and a wiring 14 are not shown in the figure. In addition, FIG. 2 is a cross section along A-A line of FIG. 3.

As shown in FIG. 1, an ESD protecting device 100 according to this embodiment, for example, is formed between a signal line for input and output, which is connected from input and output terminals to a circuit part, and a ground terminal When the voltage exceeding a rated voltage for input and output signals in the circuit part is applied to or appears on the signal line, excessive electric charges are discharged to the ground terminal via the ESD protecting device. Therefore, even if an ESD (Electro Static Discharge) occurs on the input and output signal line, the circuit part is protected from the ESD by the ESD protecting device.

The ESD device 100 according to this embodiment includes a first terminal 1, a second terminal 2, a diode D1 (a first diode), a diode D2 (a second diode), and a Zener diode D3. The first terminal 1 is electrically connected to the ground terminal. The second terminal 2 is electrically connected to the signal line which is connected to the circuit part. An anode of the diode D1 is electrically connected to the first terminal 1. A cathode of the diode D1 is electrically connected to the second terminal 2. An anode of the diode D2 is electrically connected to the second terminal 2. A cathode of the diode D2 is electrically connected to a cathode of the Zener diode D3. An anode of the Zener diode D3 is electrically connected to the first terminal 1.

If a negative overvoltage is applied to the signal line, the ESD occurs via the diode D1. In addition, if a positive overcharge is applied to the signal line, when it exceeds the breakdown voltage of the Zener diode D3, the ESD occurs via the diode D2 and the Zener diode D3. Therefore, the circuit part is protected from the negative voltage, and from a positive voltage higher than the breakdown voltage of the Zener diode D3, by the ESD protecting device 100. For example, when the input and output signals are 5 V, the Zener diode D3 is designed so that the breakdown voltage of the Zener diode D3 can be about 7 V.

The Zener diode D3 can be used alone as the ESD protecting device. However, because the breakdown voltage of the Zener diode D3 is much higher than the breakdown voltage of the diode D1 and the diode D2, the Zener diode has a capacitance much larger than that of the diode D1 and the diode D2. For this reason, when the frequency of the input and output signals is raised, the impedance for the input and output signals of the Zener diode D3 is significantly reduced. As a result, the input and output signals can leak through the Zener diode D3, and thus a Zener diode D3 cannot be used alone as the ESD protecting device for devices that operate at high frequency.

The ESD protecting device 100 according to this embodiment, as mentioned above, contains the diode D1, diode D2, and Zener diode D3. Since the diode D2 and the Zener diode D3 are connected in series, even if the capacitance of the Zener diode D3 increases, the overall value of the capacitance of the ESD protecting device 100 is not meaningfully affected. In addition, because the diode D1 and the diode D2 are connected in parallel, the capacitance of the ESD protecting device 100 is the sum of the capacitance of the diode D1 and the series capacitance of the diodes D2. But as the capacitance of the diode D3 is selected to be much higher than that of D2 and D3, the parallel capacitance is effectively the sum of the capacitances of diodes D1 and D2. Therefore, in the ESD protecting device 100 according to this embodiment, even if the breakdown voltage of the Zener diode D3 becomes low, since the capacitance is determined by the diode D1 and the diode D2, the value of the capacitance is maintained at a small value.

With reference to FIG. 2 and FIG. 3, a detailed structure of the ESD protecting device 100 according to this embodiment will be explained. The ESD protecting device 100 according to this embodiment is provided with: a p-type first semiconductor layer 3 (first conductive type first semiconductor layer), an n⁺-type second semiconductor layer 4 (second conductive type second semiconductor layer), an n⁻-type ninth semiconductor layer 5 (second conductive type ninth semiconductor layer), a p-type third semiconductor layer 6 (first conductive type third semiconductor layer), a first region 8 of the n⁻-type ninth semiconductor layer 5, an n-type fourth semiconductor layer 7 (second conductive type fourth semiconductor layer), a second region 9 of the n⁻-type ninth semiconductor layer 5, an n⁺-type fifth semiconductor layer 10 (second conductive type fifth semiconductor layer), a p⁺-type sixth semiconductor layer 11 (first conductive type sixth semiconductor layer), the interlayer dielectric 12, the wiring 14, a back electrode 13, the first terminal 1, and the second terminal 2. The respective semiconductor layers, for example, are silicon. The n⁺-type second semiconductor layer 4 is formed on or in a part on the p-type first semiconductor layer 3. The n-type dopant concentration of the n⁺-type second semiconductor layer 4, for example, is 1×10¹⁹-1×10²⁰/cm³. The n-type dopants are arsenic (As), which is more difficult to diffuse than phosphorus (P). The n⁺-type second semiconductor layer 4 is formed so that it has a prescribed planar pattern (for example, rectangular shape). The p-type dopant concentration of the p-type first semiconductor layer 3, for example, is 1×10¹⁸-1×10¹⁹/cm³. The p-type dopants of the p-type first semiconductor layer 3, for example, are boron (B).

The n⁻-type ninth semiconductor layer 5 is epitaxially grown on the p-type first semiconductor layer 3 so as to cover the n⁺-type second semiconductor layer 4. The n⁻-type ninth semiconductor layer 5 has an n-type dopant concentration lower than the n-type dopant concentration of the n⁺-type second semiconductor layer 4. The n-type dopant concentration of the n⁻-type ninth semiconductor layer 5, for example, is 1×10¹⁴-1×10¹⁵/cm³. The n-type dopants of the n⁻-type ninth semiconductor layer 5, for example, are phosphorus.

The p-type third semiconductor layer 6 penetrates in a frame shape through the n⁻-type ninth semiconductor layer 5 from the surface of the n⁻-type ninth semiconductor layer 5 and is electrically connected with the p-type first semiconductor layer 3. In other words, the p-type third semiconductor layer 6 has a square frame shape on the surface of the n⁻-type ninth semiconductor layer 5, extends in the square frame shape through the n⁻-type ninth semiconductor layer 5 in the vertical direction, and arrives at the upper surface of the p-type first semiconductor layer 3. Here, in this embodiment, the planar shape of the p-type third semiconductor layer 6 is assumed to be a square frame shape for simplicity of explanation. However, the planar shape of the p-type third semiconductor layer 6 is not limited to the square frame shape. The p-type dopant concentration of the p-type third semiconductor layer 6, for example, is 1×10¹⁸-1×10¹⁹/cm³. The p-type dopants of the p-type third semiconductor layer 6, for example, are boron (B).

In this embodiment, the p-type third semiconductor layer 6, for example, is a p-type dopant diffusion layer formed by ion-implanting p-type dopants into the n⁻-type ninth semiconductor layer 5 and diffusing the p-type dopants by a heat treatment. However, the semiconductor layer of this type is not limited to such a dopant diffusion layer. The p-type third semiconductor layer 6 can also be a growth layer embedded into a trench with a square frame shape penetrating through the n⁻-type ninth semiconductor layer 5 by vapor-phase growth.

The first region 8 of the n⁻-type ninth semiconductor layer 5 is a part of the n⁻-type ninth semiconductor layer 5 separated from the n⁻-type ninth semiconductor layer 5 by being enclosed with the p-type third semiconductor layer 6. In other words, the first region 8 of the n⁻-type ninth semiconductor layer 5 is a part of the n⁻-type ninth semiconductor layer 5 that exists within a frame constituted by the p-type third semiconductor layer 6 extending in the vertical direction.

The n-type fourth semiconductor layer 7 is adjacent to the p-type third semiconductor layer 6 in the n⁻-type ninth semiconductor layer 5. The n-type fourth semiconductor layer 7 penetrates in a frame shape through the n⁻-type ninth semiconductor layer 5 from the surface of the n⁻-type ninth semiconductor layer 5 and is electrically connected with the p-type first semiconductor layer 3. In other words, the n-type fourth semiconductor layer 7 has a square frame shape on the surface of the n⁻-type ninth semiconductor layer 5, extends in the square frame shape through the n⁻-type ninth semiconductor layer 5 in the vertical direction, and arrives at the upper surface of the p-type first semiconductor layer 3. Here, in this embodiment, the planar shape of the n-type fourth semiconductor layer 7 is assumed to be a square frame shape for simplicity of explanation. With respect to the n-type fourth semiconductor layer 7, the planar shape is not limited to the square frame shape. The n-type dopant concentration of the n-type fourth semiconductor layer 7 is higher than the n-type dopant concentration of the n⁻-type ninth semiconductor layer 5 and lower than the n-type dopant concentration of the n⁺-type second semiconductor layer 4. The n-type dopant concentration of the n-type fourth semiconductor layer 7, for example, is 1×10¹⁸-1×10¹⁹/cm³. The n-type dopants of the n-type fourth semiconductor layer 7, for example, are phosphorus.

In this embodiment, the n-type fourth semiconductor layer 7, for example, is an n-type dopant diffusion layer formed by ion-implanting n-type dopants into the n⁻-type ninth semiconductor layer 5 and diffusing the n-type dopants by a heat treatment. However, the semiconductor layer of this type is not limited to such a dopant diffusion layer. The n-type fourth semiconductor layer 7 can also be a growth layer embedded into a trench with a square frame shape penetrating through the n⁻-type ninth semiconductor layer 5 by vapor-phase growth.

The second region 9 of the n⁻-type ninth semiconductor layer 5 is another part of the n⁻-type ninth semiconductor layer 5 which is separated from the n⁻-type ninth semiconductor layer 5 by being enclosed with the n-type fourth semiconductor layer 7. In other words, the second region 9 of the n⁻-type ninth semiconductor layer 5 is another part of the n⁻-type ninth semiconductor layer 5 existing in a frame constituted by the n-type fourth semiconductor layer 7 extending in the vertical direction.

The entire area of the second region 9 of the n⁻-type ninth semiconductor layer 5 in the surface parallel with the surface of the n⁻-type ninth semiconductor layer 5 is electrically connected to the p-type first semiconductor layer 3 via the n⁺-type second semiconductor layer 4. In other words, the n-type fourth semiconductor layer 7 is formed on the n⁺-type second semiconductor layer 4 so that the inside of the frame of the n-type fourth semiconductor layer 7 is entirely positioned on the n⁺-type second semiconductor layer 4. The n-type fourth semiconductor layer 7 is formed on the n⁺-type second semiconductor layer 4 and the p-type first semiconductor layer 3 along the outer periphery of the n⁺-type second semiconductor layer 4. The n-type fourth semiconductor layer 7 is electrically connected with the n⁺-type second semiconductor layer 4.

In this embodiment, the n⁺-type second semiconductor layer 4 is formed so that it does not extend outside of the frame of the n-type fourth semiconductor layer 7, however this semiconductor layer is not limited to this configuration. The n⁺-type second semiconductor layer 4 may also be extended up into the n⁻-type ninth semiconductor layer 5 at the outside of the frame of the n-type fourth semiconductor layer 7.

The n⁺-type fifth semiconductor layer 10 is formed on the surface of the first region 8 of the n⁻-type ninth semiconductor layer 5. The n⁺-type fifth semiconductor layer 10 has an n-type dopant concentration higher than the n-type dopant concentration of the n-type fourth semiconductor layer 7. The n-type dopant concentration of the n⁺-type fifth semiconductor layer 10, for example, is 1×10¹⁹-1×10²⁰/cm³. The n-type dopants of the n⁺-type fifth semiconductor layer 10, for example, are arsenic.

The p⁺-type sixth semiconductor layer 11 is formed on the surface of the second region 9 of the n⁻-type ninth semiconductor layer 5. The p⁺-type sixth semiconductor layer 11 has a p-type dopant concentration higher than the p-type dopant concentration of the p-type first semiconductor layer 3. The p-type dopant concentration of the p⁺-type sixth semiconductor layer 11, for example, is 1×10¹⁹-1×10²⁰/cm³. The p-type dopants of the p⁺-type sixth semiconductor layer 11, for example, are boron.

The back electrode 13 is formed on the back face at the side opposite to the n⁻-type ninth semiconductor layer 5 of the p-type first semiconductor layer 3. The first terminal 1 is electrically connected to the p-type first semiconductor layer 3 via the back electrode 13.

The interlayer dielectric 12 is formed on the n⁻-type ninth semiconductor layer 5, the p-type third semiconductor layer 6, the first region 8, the n-type fourth semiconductor layer 7, the second region 9, the n⁺-type fifth semiconductor layer 10, and the p⁺-type sixth semiconductor layer 11. The wiring 14 is formed on the interlayer dielectric 12 and electrically connects the n⁺-type fifth semiconductor layer 10 with the p⁺-type sixth semiconductor layer 11 via an aperture part of the interlayer dielectric 12. The second terminal 2 is electrically connected to the n⁺-type fifth semiconductor layer 10 and the p⁺-type sixth semiconductor layer 11 via the wiring 14.

The interlayer dielectric 12, for example, is silicon oxide, however, silicon nitride or silicon oxynitride can also be used. In addition, the wiring 14 and the back electrode 13, for example, are aluminum or copper, however other general wiring materials can be used.

The Zener diode D3 includes the p-type first semiconductor layer 3 and the n⁺-type second semiconductor layer 4. The p-type first semiconductor layer 3 is the anode layer of the Zener diode D3, and the n⁺-type second semiconductor layer 4 is the cathode layer of the Zener diode D3. The anode layer 3 of the Zener diode D3 is electrically connected to the first terminal 1 via the back electrode 13.

The diode D2 includes the second region 9 of the n⁻-type ninth semiconductor layer 5 and the p⁺-type sixth semiconductor layer 11. The second region 9 of the n⁻-type ninth semiconductor layer 5 is a cathode layer of the diode D2. The p⁺-type sixth semiconductor layer 11 is an anode layer of the diode D2. The cathode layer (the second region 9) of the diode D2 is laminated on the cathode layer (the n⁺-type second semiconductor layer 4) of the Zener diode D3 and directly, electrically joined. As a result, the contact resistance of the cathode layer of the diode D2 and the cathode layer of the Zener diode D3 is lowered. The anode layer (the p⁺-type sixth semiconductor layer 11) of the diode D2 is electrically connected to the second terminal 2 via the wiring 14.

Here, as mentioned above, the n⁺-type second semiconductor layer 4 is extends into the wall of the frame form of the n-type fourth semiconductor layer 7. This permits an increase of the area of the p-n junction of the n⁺-type second semiconductor layer 4 and the p-type first semiconductor layer 3 beyond the size of the n-layer 9 bounded by the wall of the frame form 7. Therefore, the on-state resistance of the Zener diode D3 can be further lowered.

The diode D1 includes the p-type first semiconductor layer 3 and the first region 8. The p-type first semiconductor layer 3 is the anode layer of the diode D1. The first region 8 is the cathode layer of the diode D1. The anode layer (the p-type first semiconductor layer 3) of the diode D1 is common to the anode layer (the p-type first semiconductor layer 3) of the Zener diode D3 and is electrically connected to the first terminal. The cathode layer (the first region 8) of the diode D1 is electrically connected to the wiring 14 via the n⁺-type fifth semiconductor layer 10 and electrically connected with the anode layer (the p⁺-type sixth semiconductor layer 11) of the diode D2 and the second terminal 2 via the wiring 14.

The breakdown voltage of the ESD protecting device 100 according to this embodiment is determined by the breakdown voltage of the Zener diode D3. The breakdown voltage of the Zener diode D3 is regulated by the n-type dopant concentration of the n⁺-type second semiconductor layer 4.

The operation of the ESD protecting device 100 according to this embodiment will be explained. If a negative voltage is applied to the second terminal 2, the diode D1 is set to an on-state. The Zener diode D3 is set to an on-state, however the diode D2 is set to an off state. As a result, a current flows to the second terminal via the back electrode 13, the p-type first semiconductor layer 3, the first region 8, the n⁺-type fifth semiconductor layer 10, and the wiring 14 from the first terminal 1. For a negative ESD, the ESD protecting device 100 protects the circuit part by this operation.

If a positive voltage is applied to the second terminal 2, and if this voltage is the breakdown voltage or lower of the Zener diode D3, the diode D2 is set to an on-state, however, the diode D1 and the Zener diode D3 are set to an off-state. No current flows between the first terminal and the second terminal 2 of the ESD protecting device. The applying voltage is input as an input signal into the circuit part. Thus, by forming the zener diode D3 to have a breakdown voltage higher than that of the device it is protecting, normal device operation continues.

If the positive applying voltage of the second terminal 2 exceeds the breakdown voltage of the Zener diode D3, the Zener diode D3 and the diode D2 are set to an on-state. As a result, a current flows to the first terminal 1 via the wiring 14, the p⁺-type sixth semiconductor layer 11, the second region 9, the n⁺-type second semiconductor layer 4, the p-type first semiconductor layer 3, and the back electrode 13 from the second terminal 2. For a positive ESD, the ESD protecting device 100 protects the circuit part by this operation.

Here, when the Zener diode D3 breaks down, if the on-state resistance of the Zener diode D3 and the diode D2 is high, the current generated by the ESD does not flow entirely to the ESD protecting device 100, and part of the current flows to the circuit part. In other words, the ESD protection function of the ESD protecting device is reduced. A low on-state resistance is desirable in the ESD protecting device.

Next, the effects of the ESD protecting device 100 according to this embodiment are explained below.

In the ESD protecting device 100 according to this embodiment, because the diode D2 and the Zener diode D3 are connected in series, the resistance of the connecting part of the diode D2 and the Zener diode D3 is likely to be raised. However, the second region 9 as a cathode layer of the diode D2 is directly laminated on, i.e., integrally formed with, the n⁺-type second semiconductor layer 4 as a cathode layer of the Zener diode D3. For this reason, since the contact resistance of the cathode layer of the diode D2 and the cathode layer of the Zener diode D3 is low, the on-state resistance for the positive ESD is lowered in the ESD protecting device 100 according to this embodiment.

In addition, the capacitance of the ESD protecting device 100 according to this embodiment is not affected by the capacitance of the Zener diode D3 because the Zener diode D3 and the diode D2 are connected in series as mentioned above. The capacitance of the ESD protecting device 100 according to this embodiment is the sum of the capacitance of the diode D1 and effectively the capacitance of the diode D2 (as the capacitance of diode D3 is much greater, it has little impact on the series capacitance of D2 and D3 at maximum, and the value of their capacitance is much smaller than the capacitance of the Zener diode D3.

Therefore, in the ESD protecting device 100 according to this embodiment, since the cathode layer (the second region 9) of the diode D2 is directly laminated right on (formed integrally with) the cathode layer (the n⁺-type second semiconductor layer 4) of the Zener diode D3, the value of the capacitance is small, and the on-state resistance is reduced.

In addition, in the ESD protecting device 100 according to this embodiment, the diode D2 is laminated right on the Zener diode D3. For this reason, the chip area of the ESD protecting device 100 can be reduced in contrast to the case where the diode D2 and the Zener diode D3 are formed in parallel in the horizontal direction on the p-type first semiconductor layer 3.

In the ESD protecting device 100 according to this embodiment, arsenic is used as the n-type dopants of the n⁺-type second semiconductor layer 4. Since the arsenic has a diffusion coefficient smaller than that of phosphorus, the diffusion of the n-type dopants into the second region 9 from the n⁺-type second semiconductor layer 4 is suppressed. Furthermore, since the n⁺-type second semiconductor layer 4 is interposed between the second region 9 and the first semiconductor layer 3, the diffusion of the p-type dopants into the second region 9 from the p-type first semiconductor layer 3 is suppressed.

On the other hand, as the n-type dopants of the n-type fourth semiconductor layer 7, phosphorus rather than arsenic is used because its diffusion is easy. With the diffusion of the n-type dopants in the n-type fourth semiconductor layer 7, the n-type fourth semiconductor layer 7 is extended up to the p-type first semiconductor layer 3 and the n⁺-type second semiconductor layer 4 from the surface of the n⁻-type ninth semiconductor layer 5.

In addition, in the ESD protecting device 100 according to this embodiment, the n⁺-type second semiconductor layer 4 has a structure in which it does not extend outside of the frame of the n-type fourth semiconductor layer 7. However, the area of the p-n junction of the Zener diode D3 can be increased by extending the n⁺-type second semiconductor layer 4 into the n⁻-type ninth semiconductor layer 5 at the outside of the frame of the n-type fourth semiconductor layer 7. As a result, since the on-state resistance of the Zener diode D3 is reduced, the on-state resistance of the ESD protecting device 100 is further reduced. On the contrary, the capacitance of the Zener diode D3 is increased, however as mentioned above, in the ESD protecting device 100 according to this embodiment, its influence on the capacitance of the ESD protecting device 100 is little. In this case, the capacitance of the ESD protecting device 100 according to this embodiment is also maintained at a small value.

### Second Embodiment

The ESD protecting device according to the second embodiment will be explained with reference to FIG. 4. FIG. 4 is a schematic cross section showing the main parts of the ESD protecting device according to the second embodiment. Here, the same reference numbers or symbols will be given to the same constituent parts as those of the constitution explained in the first embodiment, and their explanation will be omitted. The differences from the first embodiment will be mainly explained.

As shown in FIG. 4, an ESD protecting device 200 according to this embodiment is different from the ESD protecting device 100 according to the first embodiment in that an n⁺-type second semiconductor layer 4a is not the ninth semiconductor layer but is an n-type dopant diffusion layer. In the ESD protecting device 200 according to this embodiment, the n⁺-type second semiconductor layer 4a is formed by ion-implanting arsenic at a prescribed position of the upper surface of the p-type first semiconductor layer 3 and diffusing the arsenic through the subsequent heat treatment.

In the ESD protecting device 200 according to this embodiment, because the n⁺-type second semiconductor layer 4a is formed without using the epitaxial growth, the manufacture cost is reduced. The other constitutions have advantages similar to those of the ESD protecting device according to the first embodiment.

### Third Embodiment

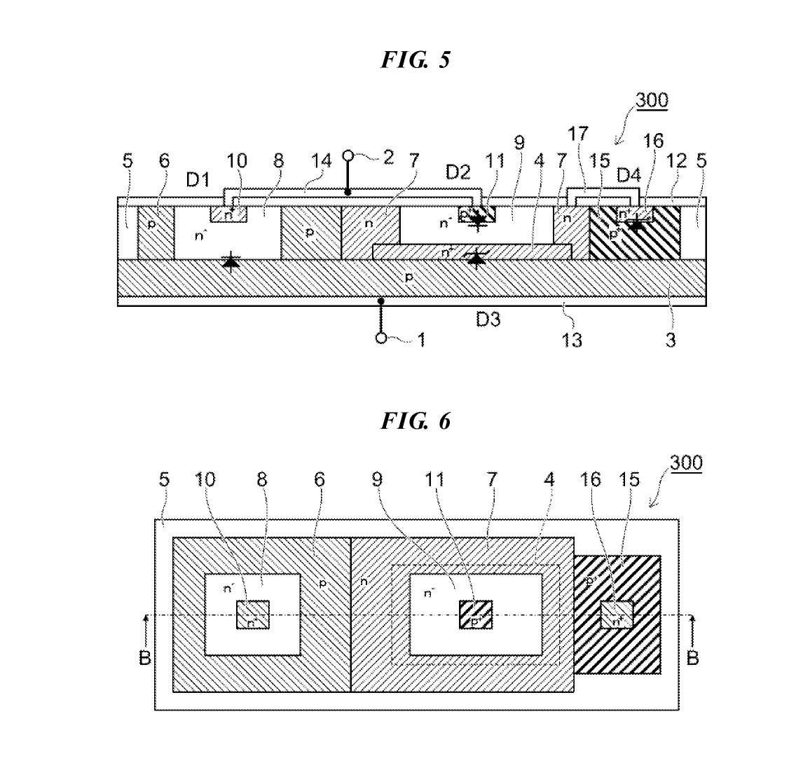

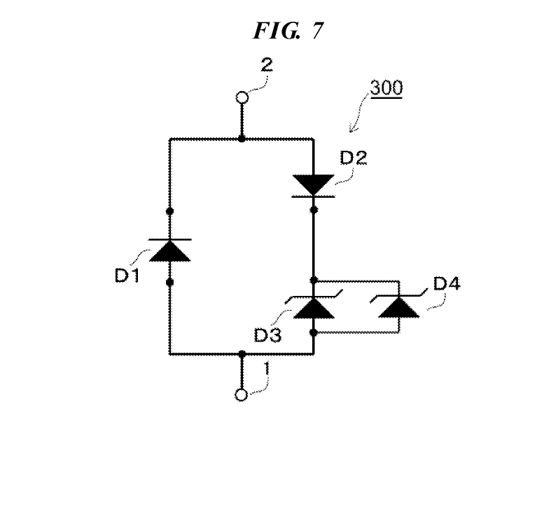

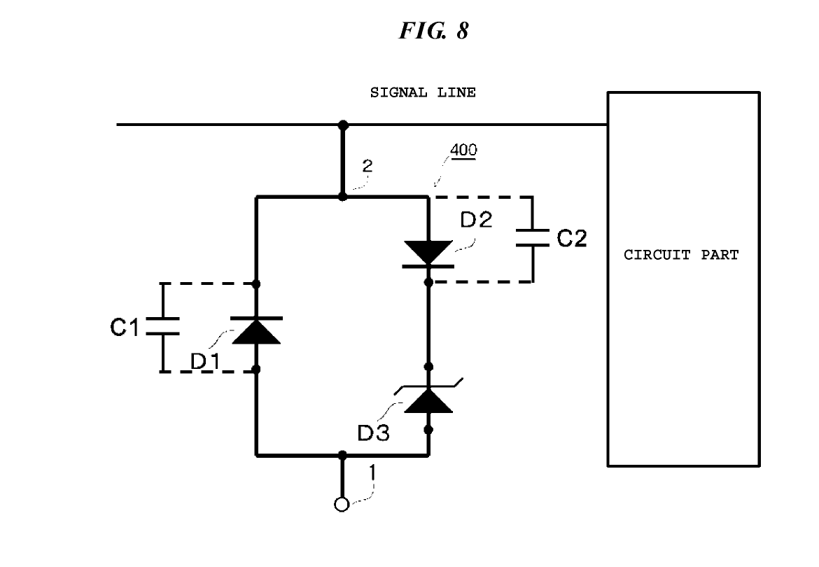

The ESD protecting device according to a third embodiment will be explained with reference to FIGS. 5-7. FIG. 5 is a schematic cross section showing the main parts of the ESD protecting device according to this embodiment. FIG. 6 is a schematic plan view showing the main parts of the ESD protecting device according to this embodiment. In the plan view of FIG. 6, the interlayer dielectric 12, the wiring 14, and a wiring 17 are not shown. In addition, FIG. 5 is a cross section along B-B line of FIG. 6. FIG. 7 shows an equivalent circuit of the ESD protecting device according to the third embodiment. Here, the same reference numbers or symbols will be given to the same constituent parts as those of the constitution explained in the first embodiment, and their explanation will be omitted. The differences from the first embodiment will be mainly explained.

As shown in FIGS. 5 and 6, an ESD protecting device 300 according to this embodiment is further provided with a p⁺-type seventh semiconductor layer 15 (first conductive type seventh semiconductor layer), an n⁺-type eighth semiconductor layer 16 (second conductive type eighth semiconductor layer), and the wiring 17, compared with the ESD protecting device 100 according to the first embodiment. The p⁺-type seventh semiconductor layer 15 is adjacent to the n-type fourth semiconductor layer 7 in the n⁻-type ninth semiconductor layer 5, penetrates through the n⁻-type ninth semiconductor layer 5 from the surface of the n⁻-type ninth semiconductor layer 5, and is electrically connected to the p-type first semiconductor layer 3. The p⁺-type seventh semiconductor layer 15 has a p-type dopant concentration higher than the p-type dopant concentration of the p-type first semiconductor layer 3. The p-type dopant concentration of the p⁺-type seventh semiconductor layer 15, for example, is 1×10¹⁹-1×10²⁰/cm³. The p-type dopants of the p⁺-type seventh semiconductor layer, for example, are boron.

The n⁺-type eighth semiconductor layer 16 is formed on the surface of the p⁺-type seventh semiconductor layer 15 and has an n-type dopant concentration higher than the n-type dopant concentration of the n-type fourth semiconductor layer 7. The n-type dopant concentration of the n⁺-type eighth semiconductor layer 16, for example, is 1×10¹⁹-1×10²⁰/cm³. The n-type dopants of the n⁺-type eighth semiconductor layer 16, for example, are arsenic.

The interlayer dielectric 12 extends onto the p⁺-type seventh semiconductor layer 15 and the n⁺-type eighth semiconductor layer 16. The wiring 17 is formed via the interlayer dielectric 12 on the p⁺-type seventh semiconductor layer 15 and the n⁺-type eighth semiconductor layer 16. The wiring 17 is electrically connected with the n-type fourth semiconductor layer 7 and the n⁺-type eighth semiconductor layer 16 via an aperture part of the interlayer dielectric 12. The wiring 17, for example, is aluminum or copper, similar to the wiring 14.

The p⁺-type seventh semiconductor layer 15 and the n⁺-type eighth semiconductor layer 16 further constitute a Zener diode D4. The p⁺-type seventh semiconductor layer 15 is an anode layer of the Zener diode D4 and is electrically connected to the first terminal 1 via the p-type first semiconductor layer 3. The n⁺-type eighth semiconductor layer 16 is a cathode layer of the Zener diode D4 and is electrically connected with the cathode layer (the n⁺-type second semiconductor layer 4) of the Zener diode D3 and the cathode layer (the second region 9) of the diode D2 via the wiring 17 and the n-type fourth semiconductor layer 7.

As shown in the equivalent circuit of FIG. 7, the Zener diode D4 is electrically connected in parallel with the Zener diode D3. In other words, in the ESD protecting device 300 according to this embodiment, the Zener diode D4 is electrically connected in parallel with the Zener diode D3, compared with the ESD protecting device 100 according to the first embodiment. From this point of view, the ESD protecting device 300 according to this embodiment is different from the ESD protecting device 100 according to the first embodiment. Therefore, in the ESD protecting device 300 according to this embodiment, the on-state resistance is further lowered while maintaining the capacitance at a small value. The other effects are similar to the effects of the ESD protecting device 100 according to the first embodiment.

### Fourth Embodiment

An ESD protecting device 400 according to a fourth embodiment will be explained with reference to FIG. 8. FIG. 8 shows an equivalent circuit of the ESD protecting device according to the fourth embodiment. Here, since a schematic cross section and a plan view showing the main parts of the ESD protecting device 400 according to the fourth embodiment are similar to those of the ESD protecting device 100 according to the first embodiment, these drawings are omitted. In addition, the same reference numbers or symbols are given to the same constituent parts as the parts of the configuration explained in the first embodiment, and their explanation is omitted.

In the ESD protecting device 400 according to the fourth embodiment, the capacitance (C2) of a diode D2 including a second region 9 and a p⁺-type sixth semiconductor layer 11 is formed so that the capacitance is larger than the capacitance (C1) of a diode D1 including a p-type first semiconductor layer 3 and a first region 8. The other configurations and operations are similar to those of the ESD protecting device 100 according to the first embodiment.

Here, to make the capacitance of the diode D2 larger than the capacitance of the diode D1, for example, the junction area of the diode D2 is increased, or the dopant concentration is raised.

The effects of the ESD protecting device 400 according to the fourth embodiment will be explained. If a positive voltage is applied to a second terminal 2 and the applied voltage exceeds the breakdown voltage of a Zener diode D3, the Zener diode D3 and the diode D2 are set to an on-state. As a result, current flows to the first terminal 1 via the wiring 14, the p⁺-type sixth semiconductor layer 11, the second region 9, the n⁺-type second semiconductor layer 4, the p-type first semiconductor layer 3, and the back electrode 13 from the second terminal 2. At that time, the voltage, which is generated in the ESD protecting device 400, is proportional to the resistance component of the ESD protecting device 400. For a positive ESD, the resistance component of the ESD protecting device 400 is determined by the sum of the resistance of the diode D2 and the resistance of the Zener diode D3. On the other hand, for a negative ESD, the resistance component of the device is determined by the resistance of the diode D1.

To reliably protect circuit parts from the current generated by the ESD, it is desirable for the voltage, which is generated in the ESD protecting device 400, to be small. However, if the resistance of the diode D1 and the diode D2 is lowered, the sum of the capacitance of the diode D1 and the capacitance of the diode D2 tends to increase. In other words, an inverse proportion relation exists between the resistance and capacitance of the ESD protecting device 400.

Like the ESD protecting device 400 according to the fourth embodiment, with the formation of the capacitance (C2) of the diode D2 so that the capacitance is larger than the capacitance (C1) of the diode D1, an action of reducing the difference between the resistance, when a positive ESD is applied, and the resistance, when a negative ESD is applied, is exerted, thus being able to suppress the inverse proportion relation. In other words, even if the resistance of the diode D1 and the resistance of the diodes D2 are lowered and the resistance component of the ESD protecting device 400 is lowered, the increase of the capacitance of the ESD protecting device 400 can be suppressed.

As mentioned above, since the ESD protecting device 400 according to the fourth embodiment can lower the resistance of the diode D1 and resistance of the diode D2, an effect of protecting the circuit parts from a current generated by the ESD can be accelerated.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An overvoltage protection semiconductor device, positioned between a transmission line transmitting variable frequency signals to or from a device to be protected and ground potential, comprising:
a first diode formed between the transmission line and ground potential and having a first capacitance and an orientation blocking current flowing from the transmission line to ground potential; and
a second diode and a third, zener, diode, positioned in series with one another, the second diode having a second capacitance and oriented to block current flowing from ground potential to the transmission line, the zener diode having a third capacitance and a breakdown voltage, oriented to block current, at a voltage less than the breakdown voltage thereof, in the direction of the transmission line to ground potential.

2. The overvoltage protection device of claim 1, wherein the cathode of the third diode and the cathode of the second diode is the same cathode.

3. The overvoltage protection device of claim 2, wherein the cathode of the third diode and the cathode of the second diode has an area, and the anode of the third diode has an area at least as large as the area of the cathode of the third anode.

4. The overvoltage protection device of claim 3, wherein the cathode of the third diode and the cathode of the second diode has an area, and the anode of the second diode has an area smaller than the area of the cathode of the second and third diodes.

5. The overvoltage protection device of claim 3, further including an electrode having an area, and the contact area of the anode of the first diode with the electrode is smaller than the contact area of the anode of the third diode with the electrode.

6. The overvoltage protection device of claim 1, where the capacitance of the third diode is sufficiently larger than the capacitance of the second diode such that the effective capacitance of the overvoltage protection device is the sum of the capacitances of the first and second diodes.

7. The overvoltage protection device of claim 6, wherein the breakdown voltage of the zener diode is greater than the desirable operating voltage of the device to be protected.

8. The overvoltage protection device of claim 7, further including a fourth, zener, diode, positioned in parallel with the third diode and in series with the second diode.

9. The overvoltage protection device of claim 7, further including a capacitor positioned in parallel with at least the first diode or the second diode.

10. The overvoltage protection device of claim 1, wherein the cathode of the first, second and third diodes is a doped semiconductor of a first dopant type, and the area of the cathode of the first diode is defined by an doped semiconductor isolation structure having a dopant of the second type and the area of the cathode of the second and third diodes is defined by an isolation structure of the first conductivity type having a dopant concentration greater than the cathode of the second and third diodes.

11. A method of protecting a device from electrostatic discharge, comprising:
providing a transmission line to the device
providing a ground potential;
providing a first diode in an orientation to block current flow from the transmission line to ground; and, integrally therewith;
providing a series connected second diode oriented to block current flow from the ground potential to the transmission line and a third, zener, diode oriented to block current flow from the transmission line to the ground potential; and
providing the zener diode with a breakdown voltage greater than the device operating voltage but less than a voltage which would damage the device.

12. The method of claim 11, further comprising the steps of:
forming a ground electrode
forming an anode of the third diode on the ground electrode;
forming the cathode of the first electrode on the ground electrode in a location adjacent to the anode of the third electrode; and
forming the cathode of the third diode and second diode over the anode of the third electrode, wherein the contact area between the anode of the third diode and the cathode of the second and third diodes is smaller than the area between the anode of the third diode and the ground electrode.

13. The method of claim 12, further including the step of forming the anode of the first diode on a portion of the cathode of the first diode and an anode of the second diode on a portion of the cathode of the second and third diodes;
wherein the area of contact between the anode of the second diode and the cathode of the second and third diodes is smaller than the area of contact between the anode of the third diode and the cathode of the second and third diodes.

14. The method of claim 13, wherein the capacitance of the third diode is greater than the capacitance of the second diode.

15. The method of claim 12, further including
forming an anode of a fourth diode adjacent to the third diode,
forming a cathode on the anode of the fourth diode, and
and
forming a wiring from the cathode of the fourth diode to the cathode of the second and third diodes.

16. The method of claim 11, further including providing a capacitor in parallel with the first or the second diodes.

17. A semiconductor device, comprising:
a first conductivity-type first semiconductor layer;
a second conductivity-type second semiconductor layer formed in a part of the first semiconductor layer;
a second conductivity-type ninth semiconductor layer that has a second conductivity-type dopant concentration lower than the second conductivity dopant concentration of the second semiconductor layer and is formed on the first semiconductor layer and the second semiconductor layer;
a first conductivity-type third semiconductor layer that reaches from a surface of the ninth semiconductor layer to the first semiconductor layer;
a first region enclosed with the third semiconductor layer in the ninth semiconductor layer;
a second conductivity-type fourth semiconductor layer that reaches from the surface of the ninth semiconductor layer to the first semiconductor layer and has a second conductivity-type dopant concentration higher than the second conductivity-type dopant concentration of the ninth semiconductor layer;
a second region on the second semiconductor layer, that is enclosed with the fourth semiconductor layer in the ninth semiconductor layer;
a second conductivity-type fifth semiconductor layer that is formed on the surface of the first region, and has a second conductivity-type dopant concentration higher than the second conductivity-type dopant concentration of the fourth semiconductor layer;
a first conductivity-type sixth semiconductor layer that is formed on a surface of the second region and has a first conductivity-type dopant concentration higher than the first conductivity-type dopant concentration of the first semiconductor layer;
a first terminal electrically connected to the first semiconductor layer; and
a second terminal electrically connected to the fifth semiconductor layer and the sixth semiconductor layer.

18. The semiconductor device according to claim 17, wherein the second semiconductor layer is formed on the first semiconductor layer by epitaxial growth.

19. The semiconductor device according to claim 17, further comprising:
a first conductivity-type seventh semiconductor layer that reaches from a surface of the ninth semiconductor layer to the first semiconductor layer and has a first conductivity-type dopant concentration higher than the first conductivity-type dopant concentration of the first semiconductor layer;
a second conductivity-type eighth semiconductor layer that is formed on a surface of the seventh semiconductor layer and has a second conductivity-type dopant concentration higher than the second conductivity-type dopant concentration of the fourth semiconductor layer; and
a wiring that electrically connects the fourth semiconductor layer with the eighth semiconductor layer.

20. The semiconductor device according to claim 19, wherein a capacitance of a second diode including the sixth semiconductor layer and the second region is greater than a capacitance of a first diode including the first semiconductor layer and the first region.
